(19) United States
(12) Patent Application Publication
(10) Pub. No.: US 2013/0099198 A1
(43) Pub. Date: Apr. 25, 2013

(54) SEMICONDUCTOR LIGHT EMITTING ELEMENT AND METHOD OF MANUFACTURING THE SAME

(71) Applicant: Akira TANAKA, Kanagawa-ken (JP)

(72) Inventor: Akira TANAKA, Kanagawa-ken (JP)

(73) Assignee: Kabushiki Kaisha Toshiba, Tokyo (JP)

(21) Appl. No.: 13/419,391

(22) Filed: Mar. 13, 2012

(30) Foreign Application Priority Data
Oct. 25, 2011 (JP) P2011-233610

(51) Int. Cl. H01L 33/04; H01L 33/30

(52) U.S. Cl. 257/13; 438/47; 257/E33.008; 257/E33.027

(57) ABSTRACT

According to one embodiment, a semiconductor light emitting element, including a first semiconductor layer with a first conductive type, a second semiconductor layer with a second conductive type, a semiconductor light emitting layer provided between the first semiconductor layer and the second semiconductor layer, a first electrode having a mesh-shaped structure with a plurality of mesh shapes provided on the first semiconductor layer opposed to the semiconductor light emitting layer, a plurality of second electrodes provided on the second semiconductor layer opposed to the semiconductor light emitting layer, each of the second electrode having a dot shape and being superimposed with the center of each of the mesh shapes in plain view with parallel to a surface of the second semiconductor layer.

### CROSS REFERENCE TO RELATED APPLICATION

This application is based upon and claims the benefit of priority from prior Japanese Patent Application No. 2011-233610, filed on Oct. 25, 2011, the entire contents of which are incorporated herein by reference.

### FIELD

Exemplary embodiments described herein generally relate to a semiconductor light emitting element and a method of fabricating the semiconductor light emitting element.

### BACKGROUND

Conventionally, in a nitride-compound semiconductor light emitting element, a translucent thin electrode film at a p-type side having a mesh shape opening is formed on a p-type nitride-compound semiconductor layer, and an electrode at an n-type side is formed on the entire surface of an n-type nitride-compound semiconductor layer.

The nitride-compound semiconductor light emitting element is thus configured such that a distribution of electrical current flowing through the nitride-compound semiconductor layers is uniformly achieved and light is extracted with decreasing shielding effect due to the electrode.

In the nitride-compound semiconductor light emitting element, the distribution of electrical carriers injected from the translucent thin electrode film at the p-type side is spread by the p-side translucent thin electrode film and the electrical carrier is recombined with another electrical carrier injected from the electrode at the n-type side. In such a manner, light emission is uniformly obtained in a wider light emitting area.

However, more uniformly the electrical current is spread, more a carrier density decreases. Thus, there is a problem that a ratio of non-radiative recombination becomes larger and a light emitting efficiency is decreased.

The carrier density can be increased by increasing flowing electrical current. On the other hand, there is a problem that the light emitting efficiency is not necessarily improved due to heat generation or the like by voltage drop.

### BRIEF DESCRIPTION OF THE DRAWINGS

FIGS. 1A, 1B are plane view and a cross-sectional view showing a semiconductor light emitting element, respectively, according to a first embodiment;

FIG. 2 is a cross-sectional view showing a semiconductor light emitting element of a comparative example according to the first embodiment;

FIGS. 3A-3D are schematic drawings showing electrical currents flow of the semiconductor light emitting element in FIGS. 3A, 3B in comparison with those of the comparative example in FIGS. 3c, 3d according to the first embodiment;

FIGS. 4A-4C are cross-sectional views sequentially showing steps of manufacturing the semiconductor light emitting element according to the first embodiment;

FIGS. 5A, 5B are cross-sectional views sequentially showing steps of manufacturing the semiconductor light emitting element according to the first embodiment;

FIGS. 6A, 6B are cross-sectional views sequentially showing steps of manufacturing the semiconductor light emitting element according to the first embodiment;

FIG. 7 is a cross-sectional view showing another semiconductor light emitting element according the first embodiment;

FIG. 8 is a cross-sectional view showing a semiconductor light emitting element according to a second embodiment;

FIGS. 9A, 9B are schematic drawings of an electrical current flow of the semiconductor light emitting element according to the second embodiment; and

FIG. 10 is a cross-sectional view showing a main part of another semiconductor light emitting element according to the second embodiment.

### DETAILED DESCRIPTION

According to one embodiment, a semiconductor light emitting element, including a first semiconductor layer with a first conductive type, a second semiconductor layer with a second conductive type, a semiconductor light emitting layer provided between the first semiconductor layer and the second semiconductor layer, a first electrode having a mesh-shaped structure with a plurality of mesh shapes provided on the first semiconductor layer opposed to the semiconductor light emitting layer, a plurality of second electrodes provided on the second semiconductor layer opposed to the semiconductor light emitting layer, each of the second electrode having a dot shape and being superimposed with the center of each of the mesh shapes in plain view with parallel to a surface of the second semiconductor layer.

According to another embodiment, a method for fabricating a semiconductor light emitting element including providing a first semiconductor layer with a first conductive type on a first surface of a substrate, providing a semiconductor light emitting layer on the first semiconductor layer, providing a second semiconductor layer with a second conductive type on the semiconductor light emitting layer, providing an insulation layer on the second semiconductor layer, forming openings in the insulation layer, providing a first electrode film on the insulation layer and embedding the first electrode film into the openings to provide first electrodes, each of the first electrodes having a dot shape, performing heat treatment to the substrate, forming a junction layer on a first surface of a supporting substrate, providing a second electrode on a second surface of the supporting substrate opposed to the first surface of the substrate, contacting the junction layer provided on the first surface of the supporting substrate to the first electrode film on a first surface of the substrate to bond the substrate and the supporting substrate, removing the substrate, and providing a third electrode having a mesh-shape structure with a plurality of mesh shapes on the first semiconductor layer, the center of each of the mesh shape being superimposed with each of the first electrode.

Hereinafter, embodiments are described by referring to the drawings.

### First Embodiment

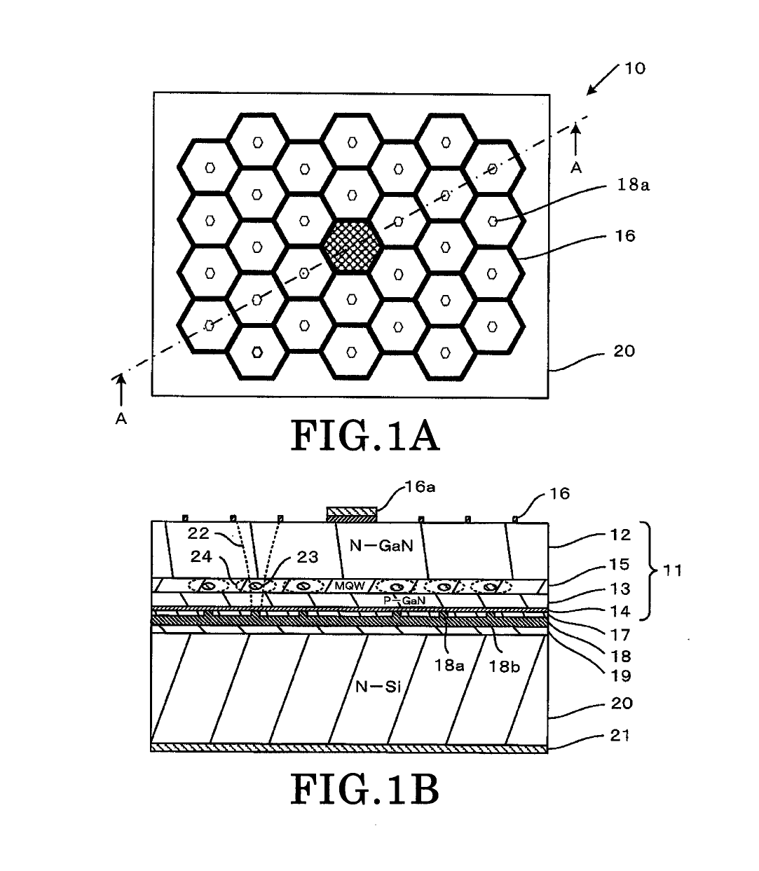

A semiconductor light emitting element according a first embodiment is described using FIG. 1. FIG. 1 is a drawing showing a semiconductor light emitting element according to the first embodiment. FIG. 1A is a plan view of the semiconductor light emitting element and FIG. 1B is a cross-sectional view which is taken along the A-A line in FIG. 1A and is seen from a direction shown by an arrow. The semiconductor light emitting element according to the first embodiment 1 is a blue light emitting diode (LED) of a nitride-compound semiconductor.

As shown in FIG. 1B, in a semiconductor light emitting element 10, a stacked semiconductor body 11 is a nitride-compound stacked semiconductor body including an n-type GaN clad layer 12 which is a first semiconductor layer with a first conductivity type, a p-type GaN clad layer 13 which is a second semiconductor layer with a second conductivity type, a p-type GaN contact layer 14, and a semiconductor light emitting layer 15 which is provided between the n-type GaN clad layer 12 and the p-type GaN clad layer 13.

A first electrode 16 is provided as a mesh-shaped structure having a plurality of mesh shapes formed by narrow wires being extended around to periphery portions on the n-type GaN clad layer 12 located on a side opposite to the semiconductor light emitting layer 15. A pad electrode 16a to bond the wires is provided in a center portion of the n-type GaN clad layer 12.

The first electrode 16 is a stacked film of titanium (Ti)/platinum (Pt)/gold (Au), which is capable of forming an ohmic contact with an n-type GaN layer, for example. The pad electrode 16a is composed of gold, for example.

In the first embodiment, each of the mesh shapes in the mesh-shaped structure has hexagon. The hexagon is a figure called planar packing which can be put together on a plane without making any gap.

Second electrodes 18a, each having a dot shape, are provided on the p-type GaN contact layer 14 on a side opposite to the semiconductor light emitting layer 15 in such a manner as to superimpose with the center of each hexagon of the first electrode 16 in a planar view when seen in parallel to the surface of the p-type GaN contact layer 14. Each second electrode 18a having the dot shape is respectively provided to correspond to each hexagon. The second electrode 18a having the dot shape is constituted with a gold (Au) film capable of forming an ohmic contact with p-type GaN, for example.

In principle, the dot shape is a point with a proper size to be determined by a contact resistance between the dot-shape second electrode 18a and the p-type GaN contact layer 14. It is preferable that the dot shape have a similar shape to the hexagon so that the in-plane distribution of electrical current in the hexagon would be symmetrical.

An insulation film 17 is provided on the p-type GaN contact layer 14 on the side opposite to the semiconductor light emitting layer 15 and in an area where the dot shape second electrodes 18 are absent. The insulation film 17 is provided to surround each of the dot-shape electrodes 18a. The insulation film 17 functions as an electrical current block layer.

An extraction electrode 18b is provided on the insulation film 17 with being in common connection with the plurality of dot shape second electrodes 18a. The dot shape second electrode 18a and the extraction electrode 18b are collectively referred to as a second electrode 18.

The insulation film 17 is a silicon oxide film, for example. It is desirable that the insulation film 17 is translucent to light emitted from the semiconductor light emitting layer 15. The extraction electrode 18b can be used as a light reflection film.

The stacked semiconductor body 11 is connected with a conductive supporting substrate 20 via the extraction electrode 18b and a junction layer 19 (a metal layer). A substrate electrode 21 (a third electrode) is formed on the supporting substrate 20 on a side opposite to the junction layer 19.

The junction layer 19 is a gold-tin (AuSn) alloy film, the supporting substrate 20 is a silicon substrate, and the substrate electrode 21 is a gold or aluminum (Al) film, for example.

A voltage is applied between the pad electrode 16a and the substrate electrode 21, so that electrical current flows through the semiconductor light emitting element 10. Then, the radiative recombination of electrical carriers injected into the semiconductor light emitting layer 15 occurs to emit light with a peak wavelength of approximately 450 nm, for example.

Although the stacked semiconductor body 11 is well known, the brief description is given below. The n-type GaN clad layer 12 also plays a role as an underlying single crystal layer for causing epitaxial growth on the semiconductor light emitting layer 15, the p-type GaN clad layer 13, and the p-type GaN contact layer 14 and is formed to be as thick as approximately 2 to 5 μm, for example.

The semiconductor light emitting layer 15 has a multiple quantum well (MQW) structure in which an InGaN barrier layer and an InGaN well layer are alternately laminated.

The InGaN barrier layer has a thickness of 10 nm and an In composition ratio of 0.05, while the InGaN well layer has a thickness of 2.5 nm and an In composition ratio of 0.2, for example. The InGaN barrier layer and the InGaN well layer are alternately laminated for eight times, for example.

The above-described semiconductor light emitting element 10 is configured so that an area with a high carrier density would be locally formed within the semiconductor light emitting layer 15 by causing the electrical current density of an area facing the dot shape second electrode 18a to be higher than a peripheral area in the semiconductor light emitting layer 15.

A light emitting efficiency of the semiconductor light emitting element 10 is determined by a balance between a lifetime of radiative recombination needed for light emissions of pairs of electrons and holes and a lifetime of non-radiative recombination needed for a heat caused by being captured by a defect.

The non-radiative recombination includes auger recombination which is proportional to the cube of the carrier density and shockley-read-hall (SRH) recombination which is proportional to the carrier density. The effect of the SRH recombination becomes larger in the case of low electrical current with a small carrier density and in a semiconductor in which the auger recombination is difficult to occur.

In such a case, the light emitting efficiency of the semiconductor light emitting element is dominated by the radiative recombination probability which is proportional to the square of mainly the carrier density and the SRH non-radiative recombination probability.

The denseness and sparseness of the carrier density are provided in the semiconductor light emitting layer 15, so that the radiative recombination probability becomes sufficiently larger than the SRH non-radiative recombination probability in the area where the carrier density is high. Thus, the light emitting efficiency becomes relatively larger.

On the other hand, in the area where the carrier density is low, the light emitting efficiency becomes relatively smaller because a difference between the radiative recombination and the non-radiative recombination becomes smaller.

Accordingly, the light emitting efficiency can be improved as a whole by optimizing the ratio of the area where the carrier density is high and the area where the carrier density is low and the in-plane distribution.

This can provide a higher light emitting efficiency as compared with the case where the distribution of electrical current flowing through the semiconductor light emitting layer 15 is simply made uniform.

The electrical current spreads substantially uniformly to the periphery of the semiconductor light emitting element 10 along the mesh-shaped first electrode 16 from the pad electrode 16a. The electrical current 22 flowing into the n-type GaN clad layer 12 from each side of the hexagon of the first electrode 16 flows towards the dot-shape second electrode 18a provided to overlap with the center of the hexagon.

The p-type GaN clad layer 13 and the p-type GaN contact layer 14 are sufficiently thinner and has a higher resistance than those of the n-type GaN clad layer 12. Thus, the spread of the electrical current along the p-type layers such as the p-type GaN clad layer 13 and the p-type GaN contact layer 14 is negligible.

As a result, the electrical current is concentrated in the area facing the dot shape second electrode 18a in the semiconductor light emitting layer 15, which causes an electrical current concentrated area 23. The carrier density of the electrical current concentrated area 23 becomes higher than that of the surroundings. Thus, alight emitting area 24 with a high light intensity is obtained.

It is preferable that the size of the hexagon mesh is approximately several tens μm to 100 μm so as not for the adjacent light emitting areas 24 to interfere with each other. In such a manner, a point in which light is concentrated in the center of the hexagon mesh can be provided with a high density. Also, the amount of the fine wires of the first electrode 16 shielding the light is small. Thus, the light emitting efficiency is improved and a large output can be provided.

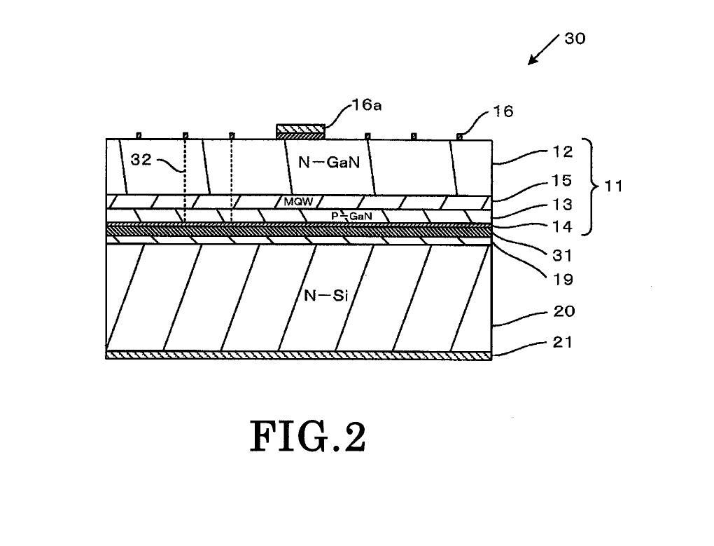

FIG. 2 is a cross-sectional view showing a semiconductor light emitting element of a comparative example. The semiconductor light emitting element of the comparative example means a semiconductor light emitting element in which a p-type GaN contact layer and a second electrode come in contact with each other via whole surfaces.

As shown in FIG. 2, a semiconductor light emitting element 30 of the comparative example has a second electrode 31 provided on a p-type GaN contact layer 14. The p-type GaN contact layer 14 and the second electrode 31 come in contact with each other via whole surfaces. Electrical current 32 flows substantially vertically towards the second electrode 31 from each side of the first electrode 16.

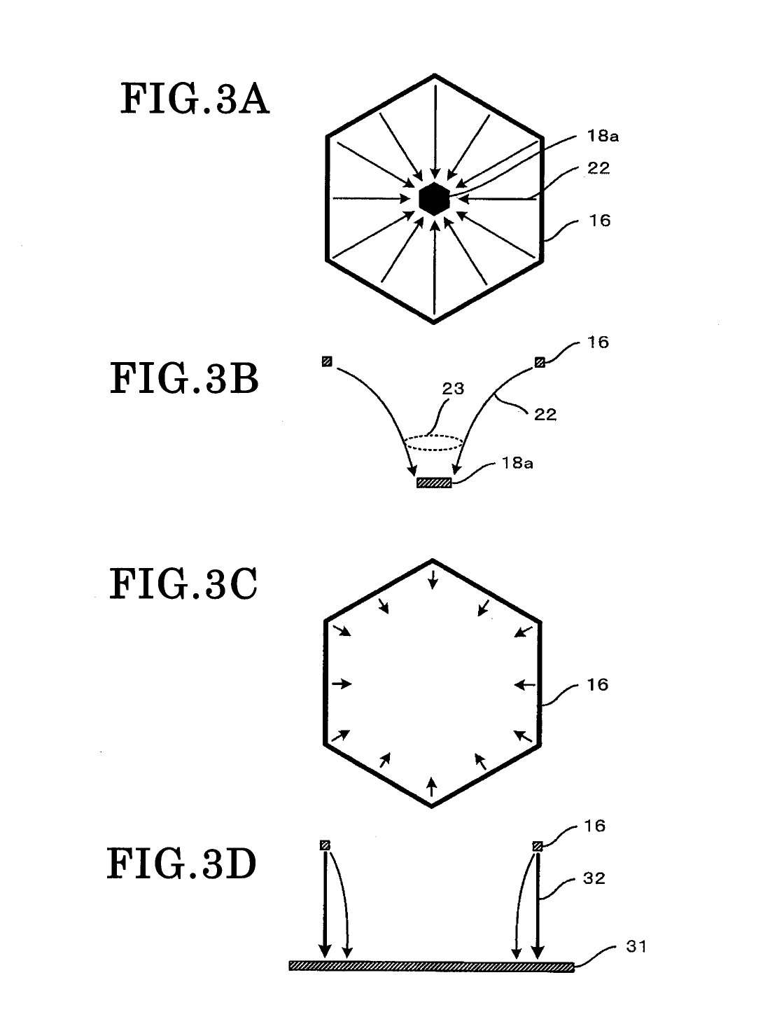

FIG. 3 shows drawings showing an electrical current flow of the semiconductor light emitting element 10 in comparison with an electrical current flow of the semiconductor light emitting element 30. FIGS. 3A and 3B are drawings showing the electrical current flow of the semiconductor light emitting element 10. FIG. 3A is a plan view and FIG. 3B is a cross-sectional view. FIGS. 3C and 3D are drawings showing the electrical current flow of the semiconductor light emitting element 30. FIG. 3C is a plan view and FIG. 3D is a cross-sectional view.

As shown in FIG. 3, the electrical current flow behaves as follows in the semiconductor light emitting element 30 of the comparative example. The electrical current 32 is the strongest directly under the first electrode 16 and becomes weaker as being apart from the first electrode 16. The electrical current hardly flows through the center of the first electrode 16.

As a result, the light emitting strength directly under the first electrode 16 becomes the highest but the light is shielded by the first electrode 16. Thus, light cannot be effectively extracted.

On the other hand, electrical current flow behaves as follows in the semiconductor light emitting element 10 of the first embodiment. As described above, electrical current 22 is concentrated towards the center of the dot shape second electrode 18a from each side of the first electrode 16. The electrical current density increases according to a ratio of the area of the hexagon and the area of the dot-shape second electrode 18a. In addition, the electrical current hardly flows directly under the first electrode 16.

As a result, the light emitting strength in the center portion of the first electrode 16 becomes the highest. Accordingly, light can be effectively extracted without being shielded by the first electrode 16.

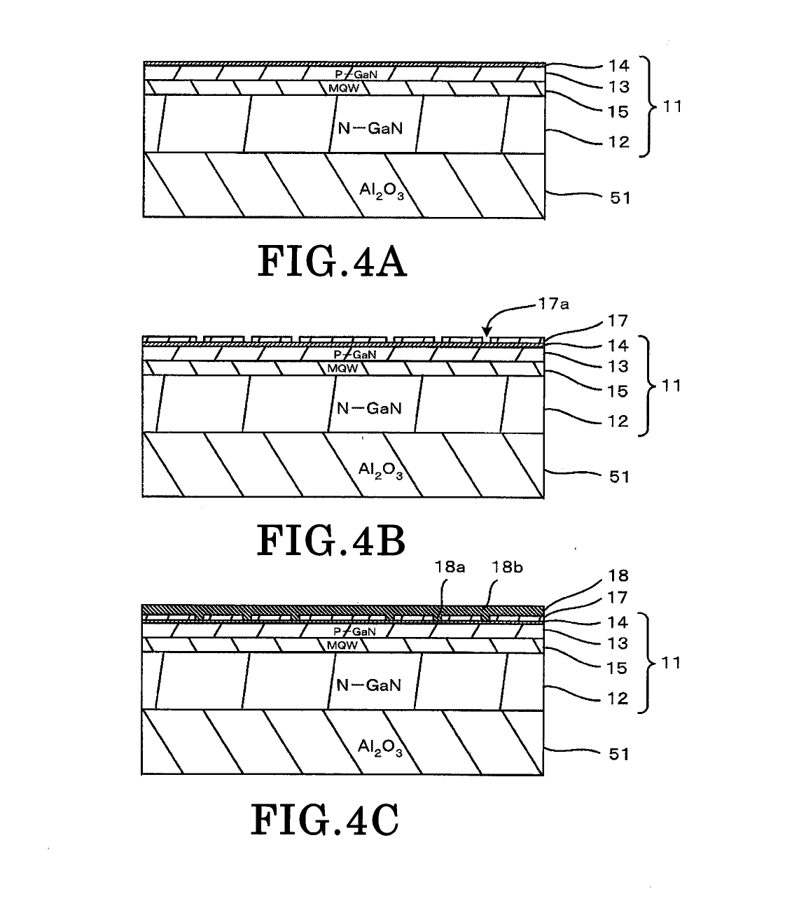

Hereinafter, a method of manufacturing a semiconductor light emitting element 10 is described. FIGS. 4 to 6 are cross-sectional views sequentially showing processes of manufacturing the semiconductor light emitting element 10.

As shown in FIG. 4A, an n-type GaN clad layer 12, a semiconductor light emitting layer 15, a p-type GaN clad layer 13 and a p-type GaN contact layer 14 are epitaxially grown in this order by metal organic chemical vapor deposition (MOCVD) on a substrate 51 for epitaxial growth, so that a stacked semiconductor body 11 is formed.

Although the process of manufacturing the stacked semiconductor body 11 is well know, the brief description is given below. A sapphire substrate with C-plane is used as the substrate 51, and organic cleaning or acid cleaning, for example, is conducted as preparation, and then the substrate 51 is stored inside a reaction chamber of an MOCVD apparatus.

Subsequently, a temperature of the substrate 51 is increased up to 1100° C., for example, by radio frequency heating in a normal pressure atmosphere of a mixed gas of nitrogen (N₂) gas and hydrogen (H₂) gas, for example. In such a manner, the surface of the substrate 51 is subjected to gas-phase etching and a natural oxide film formed on the surface is removed.

Thereafter, a mixed gas of the N₂ gas and the H₂ gas is used as a carrier gas and an ammonia (NH₃) gas and a tri-methyl gallium (TMG) gas are supplied as process gases, and a silane (SiH₄) gas is supplied as an n-type dopant. As a result, an n-type GaN clad layer 12 with a thickness of 4 μm is formed.

Subsequently, the supplies of the TMG gas and the SiH₄ gas are stopped while the supply of the N₂ gas is continued. Then, the temperature of the substrate 51 is decreased down to a temperature lower than 1100° C., for example, 800° C., and is maintained at 800° C.

Thereafter, the N₂ gas is used as a carrier gas, and NH₃ gas, the TMG gas and the tri-methyl indium (TMI) gas, for example, are supplied as process gases, to form an InGaN barrier layer with a thickness of 10 nm and an In composition ratio of 0.05. Then, an amount of supplying the TMI gas is increased to form an InGaN well layer with a thickness of 2.5 nm and an In composition ratio of 0.2.

Subsequently, the amount of supplying the TMI gas is increased or decreased to form an InGaN barrier layer and InGaN well layer, which is alternately repeated for eight times, for example. In such a manner, a semiconductor light emitting layer 15 is obtained.

Thereafter, the supply of the TMI gas is stopped while the supplies of the TMG gas and NH₃ gas are continued, so that an undoped-GaN cap layer (not shown) with a thickness of 5 nm is formed.

Subsequently, the supply of the TMG gas is stopped while the supply of the NH₃ gas is continued. Then, the temperature of the substrate 51 is increase up to a temperature higher than 800° C., for example, 1030° C., and is maintained at 1030° C.

Thereafter, a mixed gas of the N₂ gas and H₂ gas is used as a carrier gas, and NH₃ gas and the TMG gas as process gases and biscyclopentadienyl magnesium (Cp2Mg) as a p-type dopant are supplied, so that a p-type GaN clad layer 13 with a thickness of 40 nm and an Mg concentration of approximately 1×10²⁰ cm⁻³ is formed.

Subsequently, the amount of supplying Cp2Mg is increased to form a p-type GaN contact layer 14 with a thickness of 10 nm and a Mg concentration of 1E21 cm⁻³.

Thereafter, the supply of the TMG gas is stopped while the supply of the NH₃ gas is continued. Then, the temperature of the substrate 51 is naturally decreased. The supply of the NH₃ gas is continued until the temperature of the substrate 51 reaches 500° C. In such a manner, a stacked semiconductor body 11 is formed on the substrate 51 with the p-type GaN contact layer on the surface.

Next, as shown in FIG. 4B, a silicon oxide film with a thickness of approximately 100 nm is formed on the p-type GaN contact layer 14 as an insulation film 17 by chemical vapor deposition (CVD), for example. An opening 17a corresponding to the center of the first electrode 16 shown in FIG. 1 is formed in the insulation film 17 by photolithography.

Next, as shown in FIG. 4C, a gold film with a thickness of approximately 1 μm is formed on the insulation film 17 as a second electrode 18 to fill up the opening 17a by sputtering, for example, which is then subjected to heat treatment.

In such a manner, the p-type GaN contact layer 14 and the gold film are alloyed to become a second electrode 18a with a dot shape structure. The gold film formed on the insulation film 17 remains as it is to become an extraction electrode 18b.

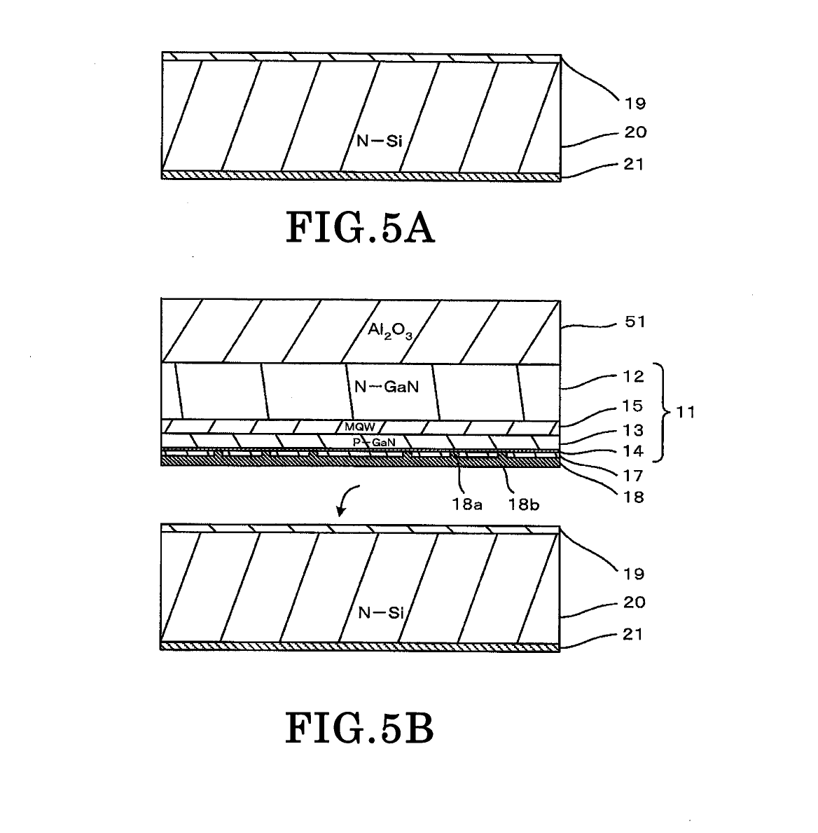

Next, as shown in FIG. 5A, a gold-tin alloy (AuSn) film with a thickness of approximately 2 μm is formed on one side of the surface of the conductive supporting substrate 20 as a junction layer 19 by vapor deposition, for example. A gold film with a thickness of approximately 1 μm is formed on the other side of the supporting substrate 20 as a substrate electrode 21 by sputtering, for example.

Next, as shown in FIG. 5B, the substrate 51 is inverted so that the second electrode 18 on the substrate 51 and the junction layer 19 on the supporting substrate face each other, and the substrate 51 and the supporting substrate overlap with each other.

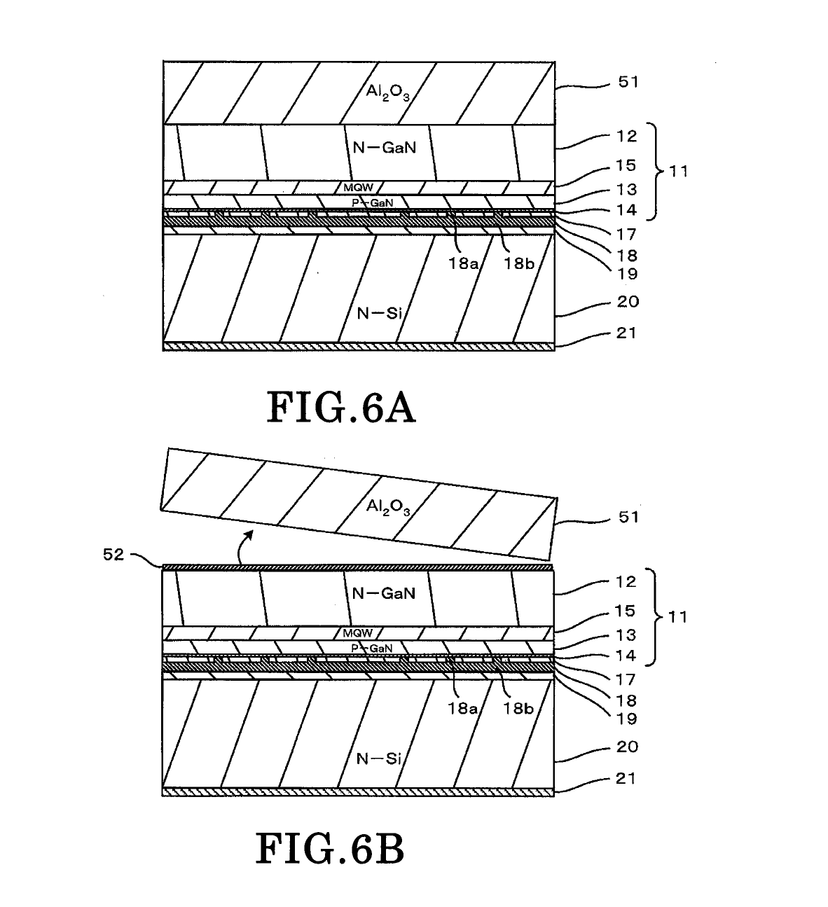

Next, as shown in FIG. 6A, the AuSn alloy film is melted by applying pressure and heat to the substrate 51 and the supporting substrate 20, so that the substrate 51 and the supporting substrate 20 are bonded with each other. Since AuSn starts melting when being heated up to approximately 300° C., the extraction electrode 18b and the junction layer 19 are fused with each other.

Next, as shown in FIG. 6B, the substrate 51 is removed by laser lift-off, for example. The laser lift-off is an approach to partially decompose an inner part of material by emitting a high-output laser beam before using the decomposed portion as a boundary to be separated.

Specifically, a laser which passes through the substrate 51 and is absorbed by the n-type GaN clad layer 12 is emitted to dissociate the n-type GaN clad layer 12. The substrate 51 and the n-type GaN clad layer 12 are thereby separated.

For example, Nd-YAG laser with a fourth harmonics (266 nm) is emitted from the substrate 51 side. Since sapphire is transparent with respect to the laser light, the emitted light passes through the substrate 51 and is effectively absorbed by the n-type GaN clad layer 12.

Since there are a number of crystal defects in the n-type GaN clad layer 12 near the interface with the substrate 51, almost all of the absorbed light is converted into heat, which results in the reaction represented by a chemical formula of “GaN=2Ga+N₂ (g)↑”. As a result, GaN is dissociated into Ga and an N₂ gas.

A dissociated Ga layer 52 is left between the substrate 51 and the n-type GaN clad layer 12. The dissociated N₂ gas is diffused inside the Ga layer 52 and is discharged to the outside.

It is preferable that the laser is focused on the n-type GaN clad layer 12 near the interface with the substrate 51. The laser may be continuous waves (CW) or pulse waves (PW). However, it is preferable that the laser be a high peak power pulse light.

A Q-switch laser, a mode lock laser, or the like, which is capable of outputting an ultrashort pulse light on the order of a picosecond to femtosecond is suitable as a high peak power pulse laser.

Thermal decomposition of the n-type GaN clad layer 12 can be conducted in such a very short period that generated heat cannot be diffused by selecting a pulse width, peak energy, repeating frequency, migration speed of a first laser 35 as needed.

Thereafter, the supporting substrate 20 is heated up to approximately 40° C. on a hot plate. Since GaN start melting when being heated up to approximately 40° C., the stacked semiconductor body 11 and the substrate 51 can be separated. The temperature at which Ga (a melting point to 30° C.) starts melting is sufficiently lower than a melting point of AuSn (up to 280° C.).

Subsequently, the Ga layer 52 left on the n-type GaN clad layer 12 is removed by hot water or being soaked in hydrochloric acid. The n-type GaN clad layer 12 is etched back by dry etching using chlorine (Cl₂)-based gas to remove the damage caused by laser irradiation.

Thereafter, a first electrode 16 with a mesh-shaped structure is formed on the n-type GaN clad layer 12 by lift-off, for example.

Specifically, a resist film with an opening pattern corresponding to the mesh-shaped first electrode 16 is formed by photolithography in alignment with the dot shape second electrode 18a which has been formed earlier. The thickness of the resist film is set to be larger than the thickness of the first electrode 16.

A gold film is formed on the n-type GaN clad layer 12 on which the resist film is formed and the resist film is removed by using solvent. Then, the gold film on the resist film is removed and the residual gold film becomes the mesh-shaped first electrode 16. In such a manner, the semiconductor light emitting element 10 shown in FIG. 1 is obtained.

As described above, in the semiconductor light emitting element 10 according to the first embodiment, the mesh-shaped first electrode 16 is provided on the n-type GaN clad layer 12 and the dot-shape second electrode 18a is provided on the p-type GaN contact layer 14 in such a manner as to overlap with the center of the hexagonal shape of the first electrode 16.

As a result, electrical current is spread to the peripheral portion to be concentrated in the dot shape second electrode 18a, so that a high carrier density area is locally formed in the semiconductor light emitting layer 15. A light emitting efficiency becomes higher in the high carrier density area other than the surroundings.

Accordingly, denseness and sparseness is provided in the carrier density as to be capable of obtaining the light emitting element with the improved light emitting efficiency as a whole. Optimization of a position in which a high carrier density area is locally formed in the semiconductor light emitting element 15 and the carrier density is easy.

The description is given herein of the case of the hexagon mesh, but the embodiment can be implemented by other shapes with capability of plane packing, such as square, equilateral triangle, and the like, for example. However, there is a possibility that the in-plane uniformity of the electrical current density is deteriorated because a difference between a distance from the center of the hexagon to the center of each side and a distance from the center of the hexagon to an end portion of each side becomes larger. When there is no particular difficulty, a regular hexagon is suitable for the mesh shape.

Although the description is given of the case where the extraction electrode 18b, being composed of the gold film, is used as a light reflection film, a silver (Ag) with a higher optical reflectivity than that of gold is used as a light reflection film so that a light output can be further increased.

In such a case, it is better that the dot shape second electrode 18a and the extraction electrode 18b are provided to be a layered film of silver and gold. Firstly, a silver film with a thickness of approximately 200 nm is formed by sputtering, for example. Subsequently, a gold film with a thickness of approximately 700 nm is formed. Then, heat treatment is conducted.

In such a manner, the silver film in contact with the p-type GaN contact layer 14 is alloyed, and a two-layered dot shape second electrode 18b being coated with gold is provided. The silver film formed on the insulation film 17 is left as it is, and a two-layered extraction electrode 18b being coated with gold is provided.

The gold coating prevents a trouble caused by alteration of silver during a manufacturing process (oxidation, sulfuration), migration, or the like from occurring. Also, since silver has a higher specific resistance and a higher heat transfer rate than gold, it is expected that electric characteristics, heat characteristics, and the like can be improved.

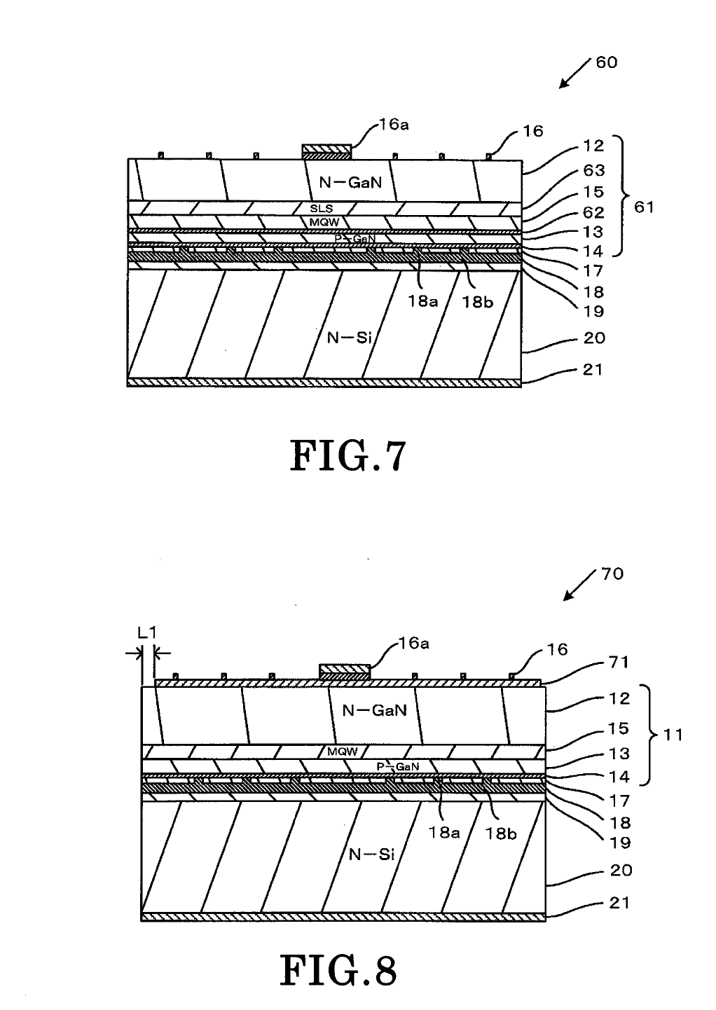

It is also possible that a p-type AlGaN overflow prevention layer and a super lattice buffer layer are provided in the stacked semiconductor body. FIG. 7 is a drawing showing a semiconductor light emitting element in which a p-type AlGaN overflow prevention layer and a super lattice buffer layer are provided in a stacked semiconductor body.

As shown in FIG. 7, in a stacked semiconductor body 61 of a semiconductor light emitting element 60, a p-type AlGaN overflow prevention layer 62 is provided between a semiconductor light emitting layer 15 and a p-type GaN clad layer 13.

The p-type AlGaN overflow prevention layer 62 has a thickness of 10 nm and an Al composition ratio of 0.15, for example. The band gap of the p-type AlGaN overflow prevention layer 62 is larger than the band gap of the p-type GaN clad layer 13.

As is well know, the p-type AlGaN overflow prevention layer 62 suppress electrons injected into the semiconductor light emitting layer 15 to go through the semiconductor light emitting layer 15, so that the carrier density in the semiconductor light emitting layer 15 is increased. This has an advantage that the light emitting efficiency is improved.

A super lattice buffer layer 63 is provided between the semiconductor light emitting layer 15 and n-type GaN clad layer 12. The super lattice buffer layer 63 includes a first InGaAlN layer and a second InGaAlN layer whose compositions are different from each other, the first InGaAlN layer and second InGaAlN layer being alternately laminated with each other.

As is well known, the super lattice buffer layer 63 suppresses a crystal defect such as dislocation to propagate from the n-type GaN clad layer 12 to the semiconductor light emitting layer 15. Thus, the crystallinity of the semiconductor light emitting layer 15 is improved. This has an advantage that the light emitting efficiency is improved.

Although the description is given of the case where the supporting substrate 20 is a silicon substrate, the supporting substrate 20 may be other conductive substrate, such as a metal substrate, or a conductive ceramic substrate.

### Second Embodiment

A semiconductor light emitting element according to a second embodiment is described referring to FIG. 8. FIG. 8 is a cross-sectional view showing a semiconductor light emitting element according to the second embodiment. In the second embodiment, same reference signs are given to denote same components as those used in the first embodiment. The description is not given to the same portions but is only given to different portions.

The second embodiment is different from the first embodiment in that a transparent conductive film is provided on an n-type GaN clad layer.

In other words, as shown in FIG. 8, a semiconductor light emitting element 70 of the second embodiment has a transparent conductive film 71 provided on an n-type GaN clad layer 12, the transparent conductive film 71 being translucent with respect to light emitted from a semiconductor light emitting layer 15.

The transparent conductive film 71 is an indium tin oxide (ITO) film with a thickness of 0.1 to 0.2 μm, for example. The A first electrode 16 having a mesh-shaped structure with a plurality of mesh shapes is provided on the transparent conductive film 71. The transparent conductive film 71 facilitates the spreading of electrical current to the periphery of semiconductor light emitting element 70.

It is better that the ITO film is formed thicker in order to spread the electrical current. On the other hand, since the ITO film absorbs light, though the amount of absorption is small, it is preferable that the ITO film is thin in order to extract light. In the following description, the transparent conductive film is also denoted as an ITO film.

The transparent conductive film 71 is formed inside the edge of the n-type GaN clad layer by a length L1, for example, 10 μm in order to suppress a surface electrical current to flow along a side surface of the stacked semiconductor body 11. It is preferable that the length L1 is 10 times or larger than a diffusion length (on the order of micrometers) of minority carriers to be injected into the semiconductor light emitting layer 15.

The n-type GaN clad layer 12 has an impurity concentration of 2×10¹⁸ cm⁻³ and a carrier mobility of approximately 300 to 400 cm²/V·s, and a specific resistance is 8×10⁻³ to 1×10⁻²Ω·cm. When the thickness of the n-type clad layer 12 is 4 μm, a sheet resistance ρₛ of the n-type GaN clad layer 12 is 20 to 25 Ω/cm².

Although the specific resistance of the transparent conductive film 71 differs based on a manufacturing method and conditions, it is possible that it is set to be 2×10⁻⁴Ω·cm. The sheet resistance ρₛ of the transparent conductive film 71 is 12 Ω/cm² or less even when the thickness capable of obtaining sufficient transmittance of 80%, for example, is 0.2 μm or less.

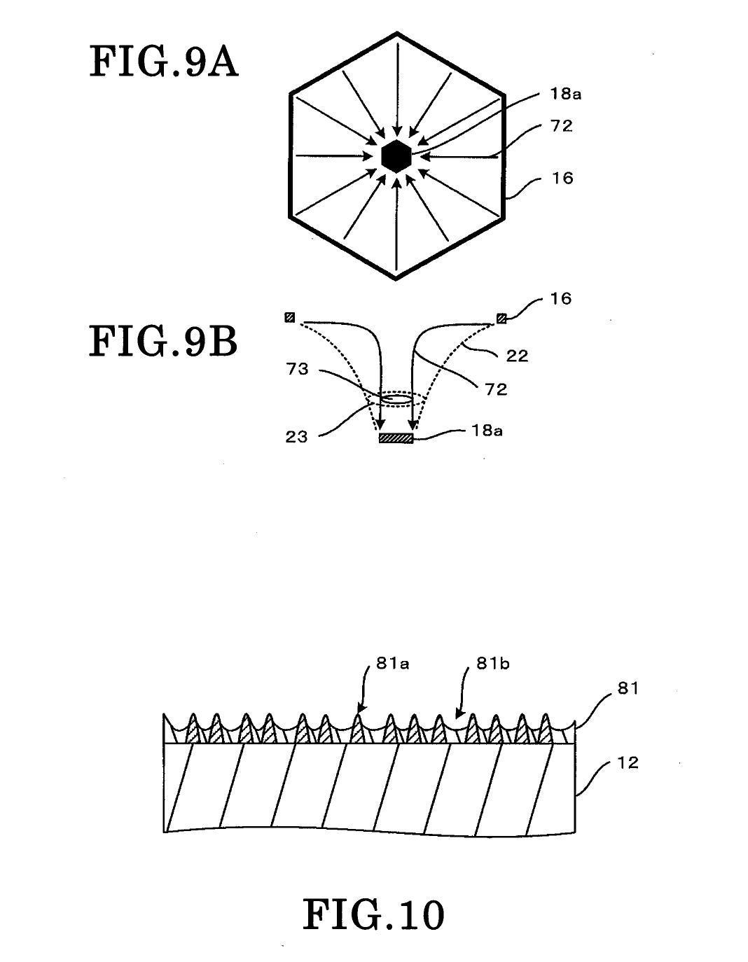

FIG. 9 is a drawing showing the electrical current flow of the semiconductor light emitting element 70 in comparison with the electrical current flow of the semiconductor light emitting element 10 shown in FIG. 1. FIG. 9A is a plan view and FIG. 9B is a cross-sectional view.

As shown in FIG. 9, electrical current flow behaves as follows in the semiconductor light emitting element 70. The electrical current 72 flows into the transparent conductive film 71 from each side of a hexagon mesh of the first electrode 16 and flows towards the center of the hexagon mesh along the transparent conductive film 71.

The electrical current 72 follows into the n-type GaN contact layer 12 from the transparent conductive film 71 in the vicinity of the center of the hexagon, and follows towards a second electrode 18a having a dot shape structure along the thickness direction of the n-type GaN contact layer 12.

As a result, the electrical current concentrated area with a size substantially equal to the size of the dot-shape second electrode 18a is formed in the semiconductor light emitting layer 15. Since the electrical current concentrated area 73 is smaller than the electrical current concentrated area 23 shown in FIG. 3, the carrier density becomes higher. Thus, the light emitting efficiency can be improved.

Next, a method of manufacturing a semiconductor light emitting element 70 is described. An ITO film is formed by sputtering, for example. In general, it is known that when an ITO film is formed by sputtering or the like, an ITO film with amorphous ITO and crystalline ITO being mixed with each other is obtained based on a substrate temperature at the deposition process, plasma density, oxygen partial pressure, and the like.

In terms of the substrate temperature, the crystallized temperature of ITO exists near 150 to 200° C., for example. When the substrate temperature is set to be near the crystallized temperature, an ITO film with amorphous ITO and crystalline ITO being mixed with each other is obtained.

The cross-section TEM (Transmission Electron Microscope) observation and electron diffraction pattern have confirmed that the crystalline ITO dispersedly exists in a form of pillar in the ITO film in such a manner as to be surrounded by the amorphous ITO.

Next, a resist film is formed on the ITO film, and the formed resist film is used as a mask to etch the ITO film. The etching of the ITO film is conducted by a mixed acid of hydrochloric acid and nitric acid, for example. The etching is conducted until the crystalline ITO and amorphous ITO are both removed.

At this process, the ITO film under the resist film is laterally etched to a side wall thereof. The etching condition is adjusted so that an undercut width would be the length L1.

The etching rate for the crystalline ITO becomes slower than the etching rate for the amorphous ITO. The etching rate for the crystalline ITO is approximately 50 to 100 nm/min, for example. The etching rate for the amorphous ITO is approximately 100 to 500 nm/min, for example.

Note that since the crystalline ITO easily remains as residue, it is preferable that etching is conducted applying supersonic waves or performing supersonic cleaning after the etching, to physically remove the crystalline ITO.

Thereafter, the heat treatment is conducted to bring the ITO film and the n-type GaN clad layer 12 into an ohmic contact with each other. The heat treatment is suitably conducted in nitrogen or in a mixed atmosphere of nitrogen and oxygen at a temperature of approximately 400 to 750° C. for approximately 10 to 20 minutes, for example. The heat treatment promotes crystallization of the ITO film and also has an effect of enhancing a conductivity of the ITO film.

As described above, in the semiconductor light emitting element 70 of the second embodiment, the transparent conductive film 71 is provided on the n-type GaN clad layer 12 and the mesh-shaped first electrode 16 is provided on the transparent conductive film 71. As a result, electrical current spreads to the center of the hexagon. Thus, the electrical current concentrated area 73 with a size substantially equal to the size of the dot shape second electrode 18a is generated in the semiconductor light emitting layer 15.

The electrical current concentrated area 73 is smaller than the electrical current concentrated area 23 shown in FIG. 3. Thus, the carrier density becomes higher. This has an advantage that the light emitting efficiency can be improved.

Although the description herein is given of the case where the transparent conductive film 71 is an ITO film, other transparent conductive film, such as a ZnO film or Sn₂O film, for example, can be equally used.

Although the description is given of the case where the transparent conductive film 71 is flat, the transparent conductive film can have an uneven surface. FIG. 10 is a cross-sectional view of an important part of a semiconductor light emitting element with an uneven surface provided on a transparent conductive film.

As shown in FIG. 10, a transparent conductive film 81 is provided on the surface of the n-type GaN clad layer 12. The transparent conductive film 81 has an unevenness formed of a projected portion 81a and a recessed portion 81b. The projected portion 81a is mainly formed of crystalline ITO and the recessed portion 81b is formed of amorphous ITO.

An incident angle of light entering the surface of the transparent conductive film 81 from the n-type GaN clad layer 12 side changes depend on the unevenness provided on the surface of the transparent conductive film 81. As a result, a ratio of light which is completely reflected by the interface between the transparent conductive film 81 and the atmosphere is decreased. This results in an advantage that light extraction efficiency is improved.

The transparent conductive film 81 with the uneven surface can be formed utilizing a difference between the etching rates between the crystalline ITO and the amorphous ITO. As described above, the selection ratio of the crystalline ITO and amorphous ITO is estimated to be about to 5.

When the transparent conductive film 81 is etched in the mixed acid of hydrochloric acid and nitric acid, the etching condition is adjusted so that the amorphous ITO with the faster etching rate is not completely removed but one portion is remained. In such a manner, the transparent conductive film 81 with the uneven surface is obtained.

Note that it is preferable that the transparent conductive film 81 be formed thicker in advance in consideration of the amount which is reduced by the etching to form the unevenness.

Note that, the uneven surface can be formed by not only the wet etching but also the dry etching, CDE (Chemical Dry Etching) or RIE (Reactive Ion Etching), for example.

Also, it is possible that an uneven surface is provided on the n-type GaN clad layer 12 and the transparent conductive film 81 is provided on the n-type GaN clad layer provided with the uneven surface. For example, the uneven surface is provided on the n-type GaN clad layer as follows.

The surface of the n-type GaN clad layer is etched by KOH solution. Since an etching rate of GaN with respect to the KOH solution is small, an uneven surface can be provided on the n-type GaN clad layer 12 due to etching unevenness. It is preferable that the KOH solution have a concentration of approximately 20 to 40% and a temperature of approximately 60 to 70° C., for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting element, comprising:
a first semiconductor layer with a first conductive type;
a second semiconductor layer with a second conductive type;
a semiconductor light emitting layer provided between the first semiconductor layer and the second semiconductor layer;
a first electrode having a mesh-shaped structure with a plurality of mesh shapes provided on the first semiconductor layer opposed to the semiconductor light emitting layer;
a plurality of second electrodes provided on the second semiconductor layer opposed to the semiconductor light emitting layer, each of the second electrode having a dot shape and being superimposed with the center of each of the mesh shapes in plain view with parallel to a surface of the second semiconductor layer.

2. The semiconductor light emitting element of claim 1, further comprising:
an insulation film provided on the second semiconductor layer other than the second electrode opposed to the semiconductor light emitting layer;
a metal layer provided on the second electrode and the insulation film;
a supporting substrate provided on the metal layer; and
a third electrode provided on the supporting substrate.

3. The semiconductor light emitting element of claim 1, wherein
each mesh has a shape of hexagon, square or equilateral triangle.

4. The semiconductor light emitting element of claim 1, wherein
a thickness of the second semiconductor layer is thicker than a thickness of the first semiconductor layer.

5. The semiconductor light emitting element of claim 1, further comprising:
a translucent conductive film on the first semiconductor layer, the translucent conductive film having translucency with light emitted from the semiconductor light emitting layer, wherein
the first electrode is provided on the translucent conductive film.

6. The semiconductor light emitting element of claim 5, wherein
concavity and convexity are provided on a surface of the translucent conductive film.

7. The semiconductor light emitting element of claim 5, wherein
the translucent conductive film is constituted with at least one selected from an ITO film, a ZnO film and a Sn₂O film.

8. The semiconductor light emitting element of claim 5, wherein
the translucent conductive film is configured to inside an edge of the first semiconductor layer, and a distance between an edge of the translucent conductive film and the edge of the first semiconductor layer is ten times or larger than a diffusion length of minority carriers injected into the semiconductor light emitting layer.

9. The semiconductor light emitting element of claim 1, wherein
the first semiconductor layer and the second semiconductor layer are constituted with an n-type GaN clad layer and both a p-type GaN clad layer and a p-type GaN contact layer, respectively.

10. The semiconductor light emitting element of claim 1, wherein
the semiconductor light emitting layer is constituted with a multiple quantum well layer in which an Inₓ₁Ga_{y1}Al_{1-x1-y1}N well layers (0<x1<1, 0<y1≦1) and an Inₓ₂Ga_{y2}Al_{1-x2-y2}N barrier layer (0x2<x1<1, 0<y1<y≦1) are alternately stacked.

11. The semiconductor light emitting element of claim 1, further comprising:
a third semiconductor layer with the second conductive type which has a larger band gap than the second semiconductor layer is provided between the second semiconductor layer and the semiconductor light emitting layer.

12. The semiconductor light emitting element of claim 11, wherein
the third semiconductor layer is constituted with a p-type AlGaN layer.

13. The semiconductor light emitting element of claim 1, further comprising:
a super lattice buffer layer in which a first InGaAlN layer and a second InGaAlN layer having a difference composition with a composition of the first InGaAlN layer are alternately stacked.

14. The semiconductor light emitting element of claim 1, wherein
the dot shape and the mesh shape have similarity each other.

15. A method for fabricating a semiconductor light emitting element, comprising:
providing a first semiconductor layer with a first conductive type on a first surface of a substrate;
providing a semiconductor light emitting layer on the first semiconductor layer;
providing a second semiconductor layer with a second conductive type on the semiconductor light emitting layer;
providing an insulation layer on the second semiconductor layer;
forming openings in the insulation layer;
providing a first electrode film on the insulation layer and embedding the first electrode film into the openings to provide first electrodes, each of the first electrodes having a dot shape;
performing heat treatment to the substrate;
forming a junction layer on a first surface of a supporting substrate:
providing a second electrode on a second surface of the supporting substrate opposed to the first surface of the substrate;
contacting the junction layer provided on the first surface of the supporting substrate to the first electrode film on a first surface of the substrate to bond the substrate and the supporting substrate;
removing the substrate; and
providing a third electrode having a mesh-shape structure with a plurality of mesh shapes on the first semiconductor layer, the center of each of the mesh shape being superimposed with each of the first electrode.

16. The method of claim 15, further comprising:
providing a translucent conductive film on the first semiconductor layer, the translucent conductive film having translucency with light emitted from the semiconductor light emitting layer, after removing the substrate and before providing the third electrodes on the first semiconductor layer.

17. The method of claim 15, wherein
concavity and convexity are provided on a surface of the translucent conductive film in providing the translucent conductive film.

18. The method of claim 15, further comprising:
providing a third semiconductor layer with a second conductive type on the semiconductor light emitting layer, third semiconductor layer having larger band gap than the second semiconductor layer, after providing the semiconductor light emitting layer and before providing the second semiconductor layer.

19. The method of claim 18, wherein
the third semiconductor layer is constituted with a p-type AlGaN layer.

20. The method of claim 15, further comprising:
alternately stacking a first InGaAlN layer and a second InGaAlN layer having a difference composition with the first InGaAlN layer to provide a super lattice buffer layer, after providing the first semiconductor layer and before providing the semiconductor light emitting layer.
